(19) United States
(12) Patent Application Publication
(10) Pub. No.: US 2007/0218612 A1
(43) Pub. Date: Sep. 20, 2007

(54) METHOD FOR FABRICATING A RECESSED-GATE MOS TRANSISTOR DEVICE

(76) Inventors: Shian-Jyh Lin, Chia-Yi Hsien (TW); Chien-Li Cheng, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 11/616,298

(22) Filed: Dec. 27, 2006

(30) Foreign Application Priority Data
Mar. 15, 2006 (TW) 095108832

(51) Int. Cl. H01L 21/8234

(52) U.S. Cl. 438/197

(57) ABSTRACT

A method for fabricating a recessed-gate transistor is disclosed. A trench is recessed into a substrate. A spacer is formed on sidewalls of the trench. A trench bottom oxide is formed. The spacer is then stripped off. A source/drain doping region is formed on the exposed sidewalls of the trench in a self-aligned fashion. The trench bottom oxide is then stripped, thereby forming a curved trench bottom and smile-shaped gate channel.

### BACKGROUND OF THE INVENTION

1. Field of the Invention

The present invention relates generally to a method for fabricating semiconductor devices such as Dynamic Random Access Memory (DRAM). More specifically, the present invention relates to a method for making recessed gate of a Metal-Oxide-Semiconductor (MOS) transistor device with a self-aligned arc-shaped trench bottom channel.

2. Description of the Prior Art

Integrated circuit devices are continually being made smaller in order to increase speed, make the device more portable and to reduce the cost of manufacturing the device. However, certain designs have a minimum feature size, which cannot be reduced without compromising the integrity of electrical isolation between devices and consistent operation of the device. For example, dynamic random access memory devices (DRAMs), which use vertical metal oxide semiconductor field effect transistors (MOSFETs) with deep trench (DT) storage capacitors, have a minimum features size of approximately 90 nm˜0.15 μm. Below that size, the internal electric fields exceed the upper limit for storage node leakage, which decreases retention time below an acceptable level. Therefore, there is a need for different methods and/or different structures to further reduce the size of integrated circuit devices.

With the continued reduction in device size, sub-micron scale MOS transistors have to overcome many technical challenges. As the MOS transistors become narrower, that is, their channel length decreases, problems such as junction leakage, source/drain breakdown voltage, and data retention time become more pronounced.

One solution to decrease the physical dimension of ULSI circuits is to form recessed gate or “trench-type” transistors, which have a gate electrode buried in a groove formed in a semiconductor substrate. This type of transistor reduces short channel effects by effectively lengthening the effective channel length by having the gate extend into the semiconductor substrate.

The recess-gate MOS transistor has a gate insulation layer formed on sidewalls and bottom surface of a recess etched into a substrate, a conductive filling the recess, contrary to a planar gate type transistor having a gate electrode formed on a planar surface of a substrate.

However, the aforesaid recessed-gate technology has some shortcomings. For example, the recess for accommodating the recessed gate of the MOS transistor is etched into a semiconductor wafer by using conventional dry etching methods. It is difficult to control the dry etching and form recesses having the same depth across the wafer. A threshold voltage control problem arises because of recess depth variation. Further, as the width of the recess shrinks, the channel length is reduced, resulting in short channel effect.

### SUMMARY OF THE INVENTION

It is one object of this invention to provide a method of fabricating a self-aligned arc-shaped or curved or rounding corner trench bottom channel for recess-gate MOS transistor devices in order to solve the above-mentioned problems.

According to the claimed invention, a method for fabricating a recessed gate MOS transistor device is disclosed. A gate trench is first etched into a semiconductor, wherein the gate trench comprises a trench bottom and trench sidewall. A spacer is formed on the trench sidewall. A trench bottom oxide is formed at the trench bottom. The spacer is removed to reveal the trench sidewall. A source/drain diffusion region is formed on the trench sidewall. The trench bottom oxide is removed to form an arc-shaped trench bottom. A gate dielectric layer is formed on the arc-shaped trench bottom. The gate trench is filled with gate material.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIGS. 1-10 are schematic, cross-sectional diagrams illustrating a self-aligned method of fabricating a recessed-gate in accordance with one preferred embodiment of this invention.

### DETAILED DESCRIPTION

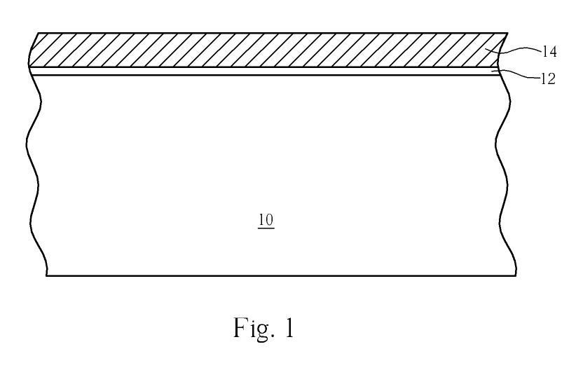

FIGS. 1-10 are schematic, cross-sectional diagrams illustrating a self-aligned method of fabricating a recessed-gate of MOS transistor devices in accordance with one preferred embodiment of this invention. As shown in FIG. 1, a semiconductor substrate 10 such as a silicon substrate, silicon epitaxital substrate or Silicon-On-Insulator (SOI) substrate is provided. A pad oxide layer 12 is then deposited on the semiconductor substrate 10. A pad nitride layer 14 is then deposited on the pad oxide layer 12.

The pad oxide layer 12 may be formed by thermal oxidation methods or using chemical vapor deposition (CVD) methods. Typically, the pad oxide layer 12 has a thickness of about 10-500 angstroms. The pad nitride layer 14 may be formed by low-pressure CVD (LPCVD) or using any other suitable CVD methods. Preferably, the pad nitride layer 14 has a thickness of about 500-5000 angstroms.

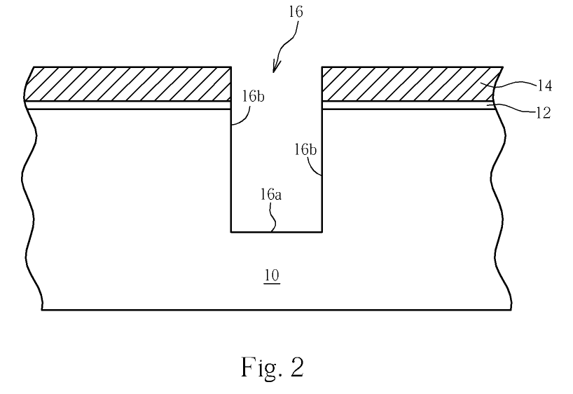

As shown in FIG. 2, a photolithographic process and a dry etching process are performed to etch a gate trench 16 into the semiconductor substrate 10. The gate trench 16 has a trench bottom 16a and trench sidewalls 16b. The photolithographic process and dry etching process for forming the trench in a substrate are well known in the art. For example, a photoresist layer (not shown) is first coated on the pad nitride layer 14. The photoresist layer is baked and subjected to exposure and development processes. A photoresist mask (not shown) is formed and an opening is formed in the photoresist mask. Using the photoresist mask as a hard mask, the gate trench is etched into the semiconductor substrate through the opening. Lastly, the photoresist mask is stripped.

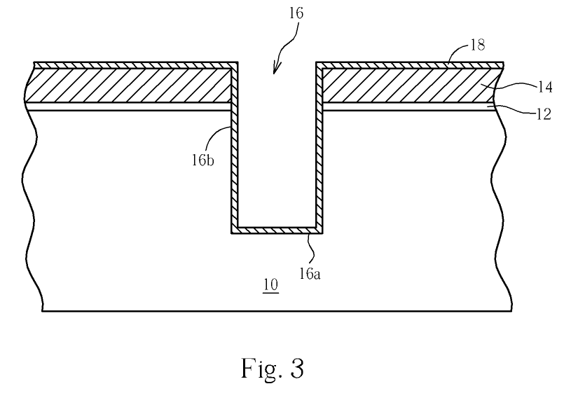

As shown in FIG. 3, after the formation of the gate trench 16, a CVD process is carried out to blanket deposit a conformal and thin silicon nitride layer 18 on the semiconductor substrate 10 and inside the gate trench 16. The silicon nitride layer 18 covers the trench sidewalls 16b and the trench bottom 16a and preferably has a thickness of about 10-500 angstroms.

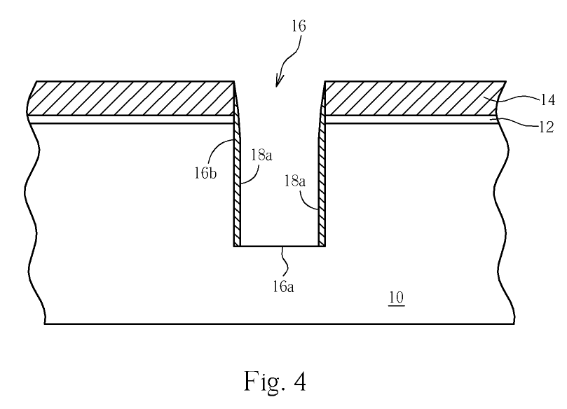

As shown in FIG. 4, anisotropic dry etching is performed to etch the silicon nitride layer 18 until the trench bottom 16a is revealed, thereby forming a silicon nitride spacer 18a on the trench sidewalls 16b.

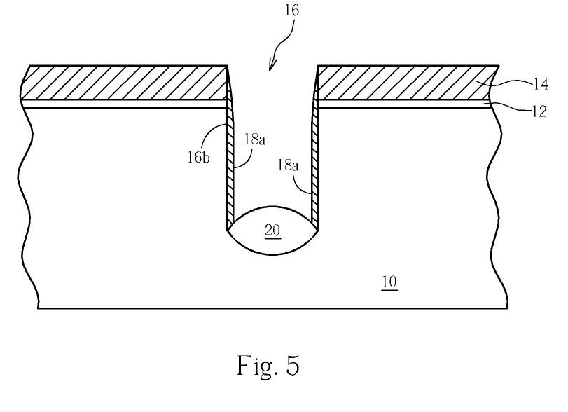

As shown in FIG. 5, after the formation of the silicon nitride spacer 18a, a thermal oxidation process such as Localized Oxidation of Silicon (LOCOS) process is performed to form a trench bottom oxide 20 at the exposed trench bottom 16a within the trench 16. At this stage, since the trench sidewall 16b is masked by the silicon nitride spacer 18a, it is not oxidized.

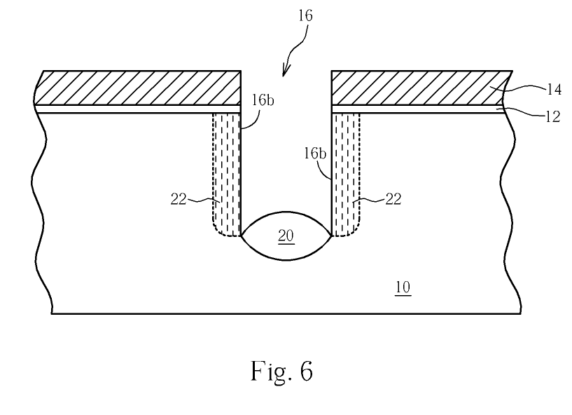

Subsequently, as shown in FIG. 6, the silicon nitride spacer 18a is removed from the trench sidewall 16b in order to reveal the trench sidewall 16b. The silicon nitride spacer 18a can be removed by conventional wet etching methods such as hot phosphoric acid solution, but not limited thereto.

After removing the silicon nitride spacer 18a, a source/drain diffusion region 22 is formed on the exposed trench sidewall 16b. To form the source/drain diffusion region 22, a Gas-Phase Diffusion (GPD) method can be employed. Alternatively, the source/drain diffusion region 22 can be formed by depositing a Phosphorus-doped Silicate Glass (PSG) layer inside the trench 16. In another case, the source/drain diffusion region 22 can be formed by tilt-angle ion implantation method.

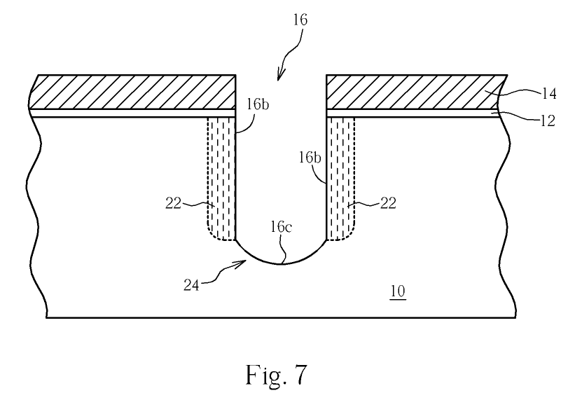

As shown in FIG. 7, after the formation of the source/drain diffusion region 22 on the trench sidewall 16b, the trench bottom oxide 20 is removed, thereby forming an arc-shaped trench bottom 16c and a smile-shaped gate channel region 24 between the source/drain diffusion regions 22. The trench bottom oxide 20 can be removed by conventional wet etching methods such as diluted hydrofluoric acid solution, but not limited thereto.

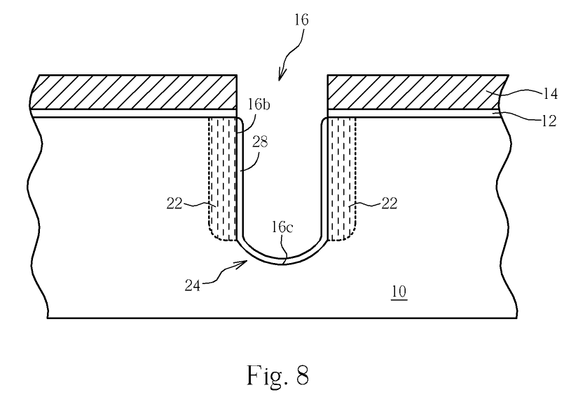

As shown in FIG. 8, a sacrificing oxide layer 28 is formed on the arc-shaped trench bottom 16c and on the trench sidewall 16b within the trench 16. According to the preferred embodiments of this invention, the sacrificing oxide layer 28 is grown on the arc-shaped trench bottom 16c and on the trench sidewall 16b using an In-Situ Steam Growth (ISSG) method. Preferably, the sacrificing oxide layer 28 has a thickness of about 10-500 angstroms.

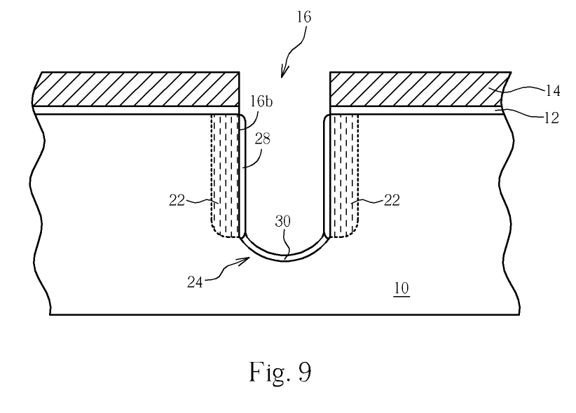

As shown in FIG. 9, an anisotropic dry etching is carried out to etch the sacrificing oxide layer 28 above the arc-shaped trench bottom 16c inside the trench 16, thereby revealing the arc-shaped trench bottom 16c. The remaining sacrificing oxide layer 28 is left on the trench sidewall 16b. Thereafter, a high-quality gate oxide layer 30 is grown on the exposed arc-shaped trench bottom 16c using, for example, ISSG method.

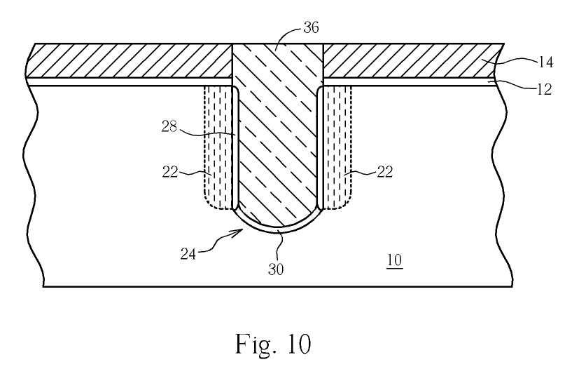

Finally, as shown in FIG. 10, the trench 16 is filled with gate material 36 such as doped polysilicon. A Chemical Mechanical Polishing (CMP) process is then performed to remove unwanted and excess gate material 36 outside the trench 16.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a recessed gate MOS transistor device, comprising:
forming a gate trench in a substrate, wherein said gate trench comprises a trench bottom and trench sidewall;
forming a spacer on said trench sidewall;
forming a trench bottom oxide at said trench bottom;
removing said spacer to reveal said trench sidewall;
forming a source/drain diffusion region on said trench sidewall;
removing said trench bottom oxide to form an arc-shaped trench bottom;
forming a gate dielectric layer on said arc-shaped trench bottom; and
forming a gate material in said gate trench.

2. The method of claim 1 wherein said spacer comprises silicon nitride.

3. The method of claim 2 wherein said spacer has a thickness of 10-500 angstroms.

4. The method of claim 1 wherein said trench bottom oxide is formed by Localized Oxidation of Silicon (LOCOS) process.

5. The method of claim 1 wherein said source/drain diffusion region is formed by Gas-Phase Diffusion (GPD) method.

6. The method of claim 1 wherein said source/drain diffusion region is formed by tilt-angle ion implantation method.

7. The method of claim 1 wherein said gate dielectric layer is formed by In-Situ Steam Growth (ISSG) method.

8. The method of claim 1 wherein said gate material comprises doped polysilicon.

9. The method of claim 1 wherein before forming said gate dielectric layer on said arc-shaped trench bottom, the method further comprises:
forming a sacrificing oxide layer on said trench sidewall and said arc-shaped trench bottom; and
performing a dry etching process to etch the sacrificing oxide layer thereby revealing the arc-shaped trench bottom.
